(19) United States
(12) Patent Application Publication
(10) Pub. No.: US 2006/0259620 A1
(43) Pub. Date: Nov. 16, 2006

(54) Statistical information collecting method and apparatus

(76) Inventor: Hiroaki Tamai, Kanagawa (JP)

Correspondence Address: KATTEN MUCHIN ROSENMAN LLP, 575 MADISON AVENUE, NEW YORK, NY, 10022-2585, US

(21) Appl. No.: 10/567,589

(22) PCT Filed: Oct. 10, 2003
(86) PCT No.: PCT/JP03/13075

§ 371 Date: Feb. 6, 2006

(51) Int. Cl. G06F 15/173; H04L 12/26; H04J 3/14; H04L 1/00; G01R 31/08; G06F 11/00; G08C 15/00; H04J 1/16

(52) U.S. Cl. 709/225; 370/232

(57) ABSTRACT

When a kind of statistic information to be extracted depends on a user policy and the kind of the statistic information is unable to be preliminarily specified, in order to provide a statistic information extraction method and device which can accommodate thereto, a table for retrieving a pattern to which a user policy is reflected is set, the pattern is retrieved from received packets based on the table, and statistic information of the pattern retrieved is stored. Also, whether or not the received packet should be made a learning object is set in the table, and a pattern unable to be retrieved is added to the table if the received packet is set as the learning object in the table when the pattern is unable to be retrieved.

### CROSS-REFERENCE TO RELATED APPLICATION

This application is a continuation of International Application PCT/JP03/13075 filed on Oct. 10, 2003, the contents of which are herein wholly incorporated by reference.

### BACKGROUND OF THE INVENTION

1. Field of the Invention

The present invention relates to a statistic information extraction (or collection) method and device, and in particular to a method and device extracting desired statistic information concerning a relay device or the like by a user's desire, i.e. a user policy.

2. Description of the Related Art

FIG. 9 shows a prior art statistic information extraction method and device. In this prior art example, a relay device 1 is specifically made an object from which desired statistic information (information about a type of packets transmitted, a user terminal having transmitted the packets, a quantity of the packets transmitted, and the like) by a user policy is extracted.

Various hard logics are incorporated into the object relay device 1. In this example, a packet identifying portion 6 among them specifically extracts statistic information according to a user policy by determining/analyzing a packet P1 received from an external network, and provides the information in the form of a signal S10 to a statistic information memory 4 that is a counter. A packet P2 after having passed through the packet identifying portion 6 is transmitted to an external network through another hard logic.

To this end, the packet identifying portion 6 is composed of an L2 protocol header determining portion 61, an L3 protocol header determining portion 62, an L3 protocol header analyzing portion (error determining portion) 63, and an L4 protocol header determining portion 64, in which by preliminarily composing the determining portions and the analyzing portion with hard logics, the desired statistic information by the user policy is extracted.

Namely, when four kinds of IPv4 frames classified depending on whether a frame has a tag or not, as well as whether the frame is a TCP protocol or a UDP protocol as shown in FIGS. 10A-10D are inputted to the packet identifying portion 6 as the packet P1, firstly, the L2 protocol header determining portion 61 determines an L3 protocol based on values of a “frame type/frame length” field in FIGS. 10A and 10C, or values of a “tag identifier” field shown in FIGS. 10B and 10D. In the case of the IPv4 (TCP/UDP) frame tagged shown in FIGS. 10B and 10D, a value “8100” (noted in hexadecimal; likewise in the following description) of the tag identifier is set in a predetermined position (offset value “96”, length “16”) as shown. When the value “8100” is not set in the position, it is indicated that the “frame type/frame length” field (TCP/UDP protocol type) of the tagless IPv4 frame as shown in FIGS. 10A and 10C is set.

Also, the L3 protocol header determining portion 62 specifies a user by the protocol type “TCP” or “UDP” in a “protocol” field, or a value of an “IP source address” field of the IPv4 frames shown in FIGS. 10A-10D. In addition, the L3 protocol header analyzing portion (error determining portion) 63 performs the detection of an error packet by a value of “TTL (Time To Live)” field. Furthermore, a hard logic is preset so as to determine a user application and to specify an arbitrary flow per user.

A determination result by the determining portions 61, 62, and 64 and an analysis result by the analyzing portion 63 are provided to a statistic information memory (counter) 4 in the form of a signal S10 as statistic information based on the user policy.

Although not shown, the number of IPv4 unicast routing frames and the number of IPv4 multicast routing frames can be also counted by the combination of “MAC destination address”, “frame type”, and “IP destination address”. Also, it becomes possible to count the number of unicast bridging frames and the number of multicast bridging frames by the “MAC destination address”.

On the other hand, there is a fault information processing method by which fault information detected by a circuit interface is temporarily stored in a memory provided to a circuit board, a statistic value of the fault information is notified to a controller from the above-mentioned circuit board in response to transfer instructions from the controller, and the detail of the above-mentioned fault information is notified to the controller from the above-mentioned circuit board in response to other transfer instructions from the controller (see e.g. patent document 1).

[Patent Document 1] Japanese Patent Application Laid-open No. 10-23011 (Column 7 [0015], FIG. 1) In the case of the above-mentioned prior art statistic information extraction method and device, there is a problem that a case where the statistic information to be extracted is changed by changing a user policy can not be flexibly addressed.

Namely, in the case of the packet identifying portion 6 of the hard logic configuration shown in FIG. 9, it is required to assemble a large-scale hard logic in order to accommodate to changes of the user policy in a network relay device (router device) binding up several thousands to several tens of thousands of user traffics. By the prior art method and device, implementation on a hardware basis is getting more difficult.

Also, for example, when a specific error occurs requiring the number of error frames per IP source address and IP destination address to be counted, a method of determining the counters to be extracted composed of hard logics requires numerous statistic information counters corresponding to the number of error frames, leading to a problem that the capacity of a statistic information memory becomes extremely large.

### SUMMARY OF THE INVENTION

It is accordingly an object of the present invention to provide a statistic information extraction method and device which can accommodate to a case where a kind of statistic information to be extracted by a user policy is changed and a case where a kind of statistic information can not be preliminarily specified.

In order to achieve the above-mentioned object, a statistic information extraction method according to the present invention comprises: a first step of setting a table for retrieving a pattern to which a user policy is reflected; a second step of retrieving the pattern from received packets based on the table; and a third step of storing statistic information of the pattern retrieved.

Namely, in the present invention, a table for enabling a retrieval of a pattern to which a user policy is reflected is set at the first step. At the second step, based on the table set at the first step, the pattern to which the above-mentioned user policy is reflected is retrieved from received packets. At the third step, statistic information of the pattern retrieved at the second step is stored. By changing the table corresponding to the user policy, various patterns are retrieved, thereby enabling the statistic information of the pattern to be stored.

At the above-mentioned first step, whether or not the received packet should be made a learning object may be set in the above-mentioned table, and in this case at the above-mentioned second step a pattern unable to be retrieved may be added to the table if the received packet is set as the learning object in the table when the pattern is unable to be retrieved.

Thus, even when the kind of the statistic information can not be preliminarily specified, it becomes possible to newly store, by learning, the statistic information of such a pattern unable to be specified.

Also, at the above-mentioned first step, a packet type, an error type, and a pattern extraction position within a received packet corresponding to those types may be set in a first table, and further a retrieval pattern corresponding to the pattern extraction position may be set in a second table.

Furthermore, the above-mentioned first step may set the first and the second table separately, and may retrieve both tables in a partially and mutually associated manner.

Thus, by increasing the number of tables, there is an advantage of accumulating the statistic information in a memory after retrieving patterns with a small memory.

Only when types of the received packet correspond to both of the above types set in the first table, the above-mentioned second step may retrieve, from the second table, a retrieval pattern at the pattern extraction position corresponding to the both types.

On the other hand, the above-mentioned first step may set the packet type and the error type in a hard logic, in which the above-mentioned second step may retrieve the pattern extraction position from the first table based on the packet type and the error type identified by the hard logic, and may further retrieve, from the second table, the retrieval pattern corresponding to the pattern extraction position.

Thus, supposing that a packet type and an error type which are regarded as important are to be preliminarily determined or analyzed without fail, the setting in the hard logic is performed in the same way as the prior art example, and the user policy is reflected to other tables, thereby enabling a determination or analysis processing rate to be improved.

It is to be noted that the above-mentioned third step may count the retrieved pattern, and may make the count the statistic information.

A statistic information extraction device realizing the statistic information extraction method according to the above-mentioned present invention may comprise: a first means setting a table for retrieving a pattern to which a user policy is reflected; a second means retrieving the pattern from received packets based on the table; and a third means storing statistic information of the pattern retrieved.

The above-mentioned first means may set in the table whether or not the received packet should be made a learning object, and the second means may add to the table a pattern unable to be retrieved if the received packet is set as the learning object in the table when the pattern is unable to be retrieved.

Also, the above-mentioned first means may set in a first table a packet type, an error type, and a pattern extraction position within a received packet corresponding to those types, and may further set in a second table a retrieval pattern corresponding to the pattern extraction position.

In addition, the above-mentioned first means may set the first and the second table separately, and may retrieve both tables in a partially and mutually associated manner.

Also, only when types of the received packet correspond to both types set in the first table, the above-mentioned second means may retrieve, from the second table, a retrieval pattern at the pattern extraction position corresponding to the both types.

Also, the above-mentioned first means may further comprise a hard logic identifying the packet type and the error type, and the second means may retrieve the pattern extraction position from the first table based on the packet type and the error type identified by the hard logic, and may further retrieve, from the second table, the retrieval pattern corresponding to the pattern extraction position.

It is to be noted that the above-mentioned third means may count the retrieved pattern, and may make the count the statistic information.

### BRIEF DESCRIPTION OF THE DRAWINGS

The above and other objects and advantages of the invention will be apparent upon consideration of the following detailed description, taken in conjunction with the accompanying drawings, in which the reference numerals refer to like parts throughout and in which:

FIG. 1 is a block diagram showing an embodiment of a device for realizing a statistic information extraction method according to the present invention;

FIG. 2 is a diagram showing an embodiment of a table A within a pattern extracting portion used for the embodiment shown in FIG. 1;

FIGS. 3A and 3B are diagrams showing a packet example 1 retrieved by referring to the table A shown in FIG. 2;

FIGS. 4A and 4B are diagrams showing a packet example 2 retrieved by referring to the table A shown in FIG. 2;

FIG. 5 is a diagram showing a relationship between a table B within a pattern extracting portion and a statistic information memory (counter) used for the embodiment shown in FIG. 1;

FIGS. 6A and 6B are diagrams showing another embodiment of a table A within a pattern extracting portion used for the embodiment shown in FIG. 1;

FIG. 7 is a diagram showing another embodiment of a table B within a pattern retrieving portion used for the embodiment shown in FIG. 1, which corresponds to the table A shown in FIGS. 6A and 6B;

FIG. 8 is a block diagram showing another embodiment of a device for realizing the statistic information extracting method according to the present invention;

FIG. 9 is a block diagram showing a device for realizing a prior art statistic information extracting method by using a packet identifying portion of a hard logic configuration used for the present invention and the prior art; and

FIGS. 10A-10D are format diagrams showing various IPv4 frames used for the present invention and the prior art.

### DESCRIPTION OF THE EMBODIMENTS

### Embodiment 1

FIG. 1 shows an embodiment of a device realizing a statistic information extraction method according to the present invention. In this embodiment, a relay device 1 which forms an object of a statistic information extraction device is composed of a pattern extracting portion 2, a pattern retrieving portion 3 composed of a CAM or the like, a statistic information memory 4 which is a counter, and a CPU 5 performing various settings according to a user policy.

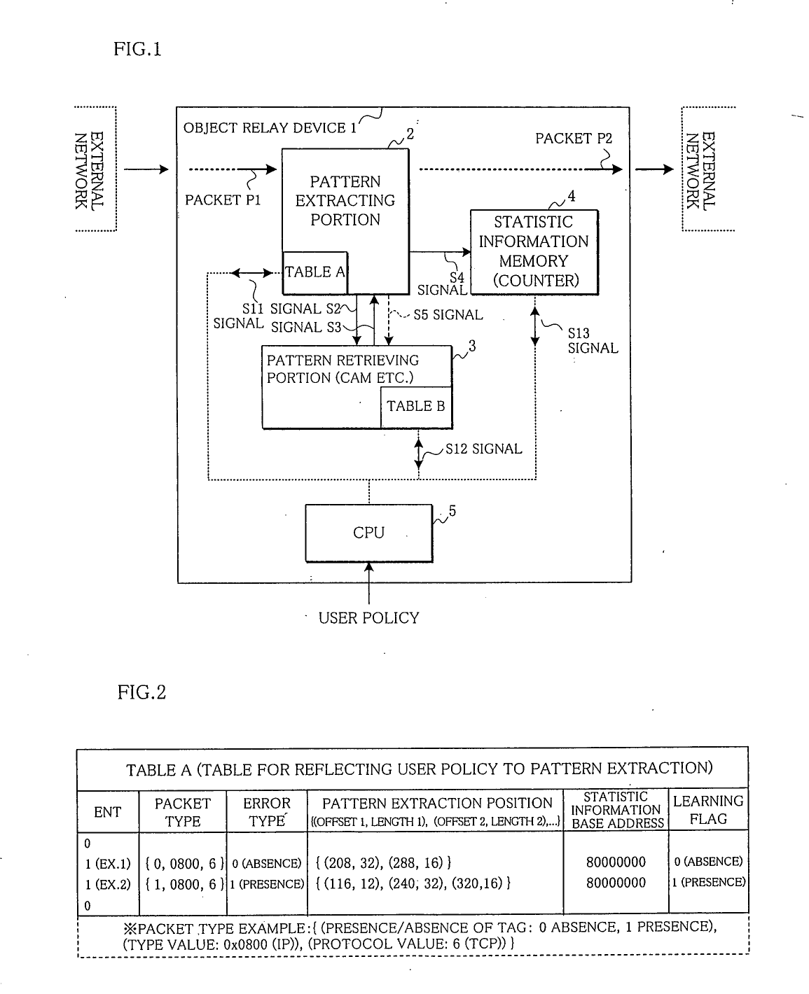

The pattern extracting portion 2 is provided with a table A shown in FIG. 2 which is for retrieving a pattern for reflecting a user policy to a pattern extraction, and is composed of an entry (ENT), a packet type, an error type, a pattern extraction position, a statistic information base address, and a learning flag.

Namely, in this table A,
1. presence/absence of tag,
2. IPv4 frame,
3. TCP protocol, and
4. errorless frame
   are confirmed by a packet type and an error type. A pattern extraction position is set corresponding to the types. The statistic information base address and the learning flag are referred corresponding to the pattern extraction position.

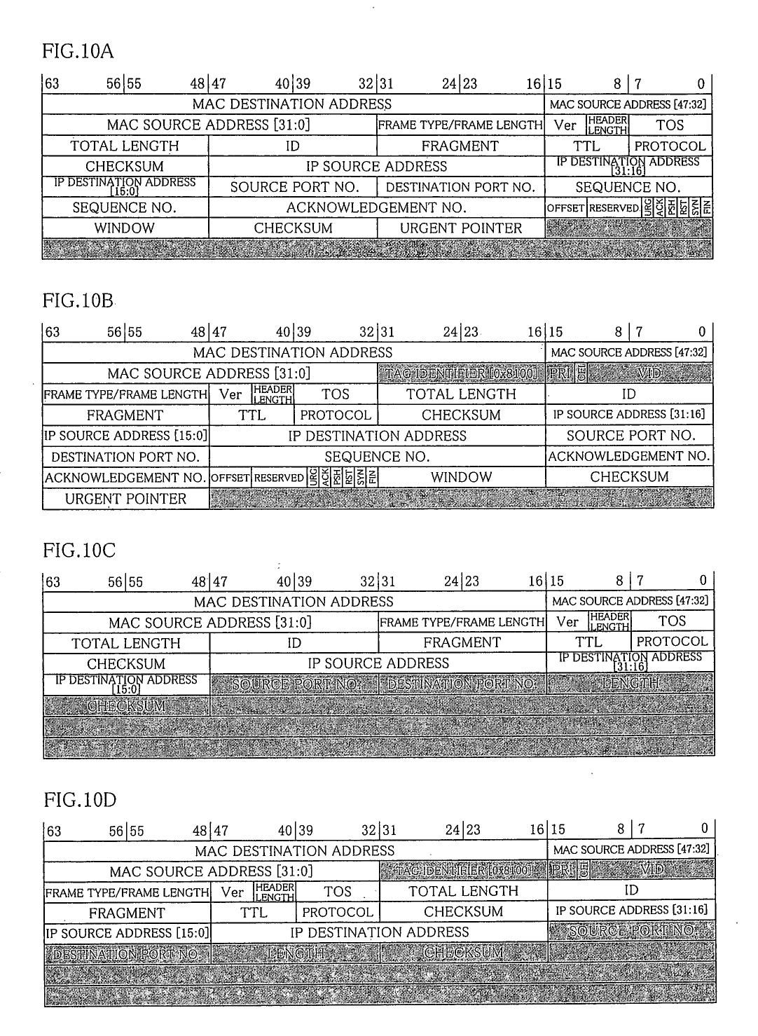

Therefore, the packet type is composed of {presence/absence of tag, type value, protocol value}. If a tag identifier (ID) value “8100” is set in a predetermined field as shown in FIGS. 10B and 10D, the “presence/absence of tag” is set with the tag presence (tagged)=“1”. If the tag identifier value “8100” is not set, the “presence/absence of tag” is set with the tag absence (tagless)=“0”. As for the “type value”, a value “0800” is set therein if a frame is IPv4 in the “frame type” field shown in FIGS. 10A-10D. As for the “protocol value”, “6” is set therein if the “protocol” field in FIGS. 10A-10D is a TCP protocol. Thus, a packet type is classified.

Also, as for the error type, “1” is set therein as indicating an error-existing (or erred) packet (frame) if “00” is indicated in the “TTL” field in FIGS. 10A-10D.

In a packet example (pattern example) 1 of FIG. 2, the packet type for the pattern retrieval of the received packet is {0, 0800, 6}, which indicates that for the packet in which the tag identifier “8100” is not set, it is set to the IPv4 since the type value is “0800” and set to the TCP since the protocol value is “6”. Also, it is indicated that a packet set errorless in the “TTL” field is made a retrieval object. In a packet example (pattern example) 2, since the packet type for the pattern retrieval of the received packet is {1, 0800, 6}, it is indicated that for a packet in which the tag presence “1” is set, it is set to the IPv4 since the type value is “0800” and set to the TCP since the protocol value is “6”. Also, it is indicated that a packet in which the error presence (error existing) “1” is set is made a retrieval object.

In the case of the packet example 1, as a retrieval object pattern extraction position, two sets of offset and length (offset 1=“208”, length 1=“32”; offset 2=“288”, length 2=“16”) are set. In the case of the packet example 2, three sets of offset and length (offset 1=“116”, length 1=“12”; offset 2=“240”, length 2=“32”; offset 3=“320”, length 3=“16”) are set. It is to be noted that the statistic information base address “80000000” is set in the packet examples 1 and 2, and “0” (non-learnt), or “1” (learnt) is respectively set in a learning flag. These will be described later.

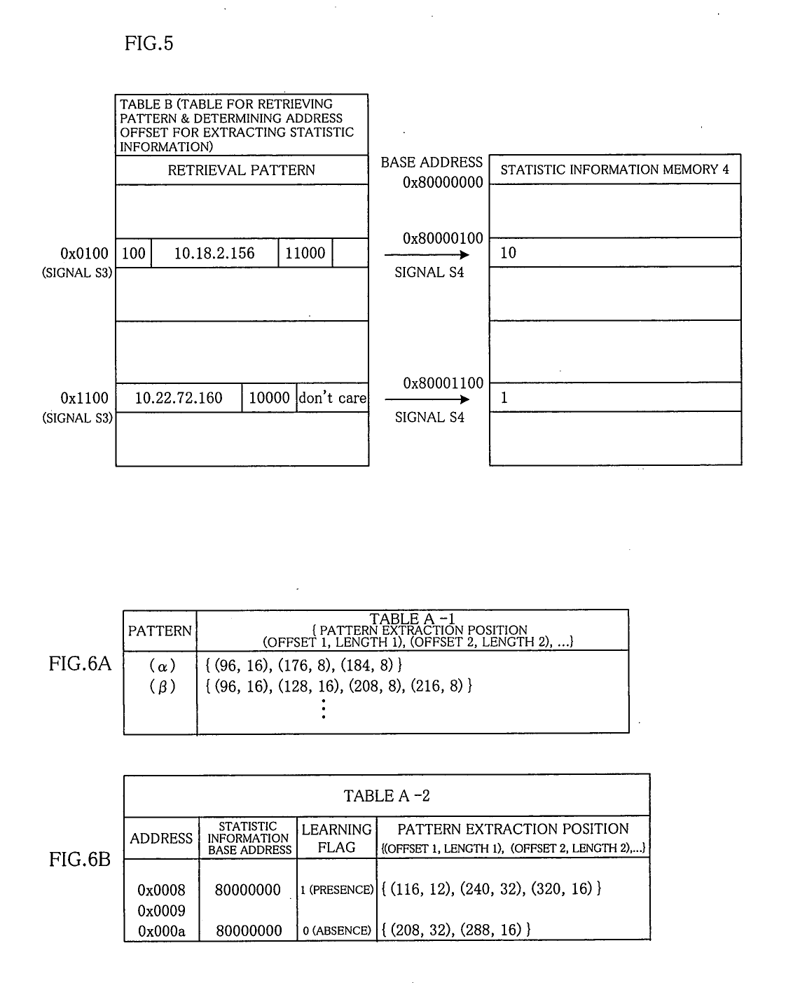

Also, in the pattern retrieving portion 3, a table B is set. This table B is for determining an address offset value for storing a pattern as statistic information (count) in the memory 4 when the pattern is retrieved based on the pattern extraction position set in the table A as shown in FIG. 5, which will be described later.

[Reception Packet Example (Pattern Example) 1]

In operation of the relay device 1 as the statistic information extraction device shown in FIG. 1, it is supposed that a packet P1 from a user X (not shown) is received through an external network. The user packet P1 is an Ether (registered trademark) frame, has no tag identifier set (tagless frame), and is set as the IPv4 (Ethernet II form) frame, the TCP, and an application using a TCP destination port No. “10000” (e.g. application of data transfer concerning a predetermined business) (packet example 1).

The pattern extracting portion 2 having received the packet P1 of the packet example 1 retrieves from the frame format shown in FIGS. 10A-10D, referring to the packet type and the error type of the table A, {tag absence=“0”, type value=“0800” (IPv4), protocol value=“6” (TCP)} as the packet type, and error absence (errorless)=“0” as the error type (TTL), and generates a retrieval pattern for the table B in the pattern retrieving portion 3 by using the information of the pattern extraction position of the entry of the packet example 1.

If it is supposed that the tagless IPv4 frame is used as shown in FIG. 10A or 10C for the packet example 1 and an IP source address is used as the information identifying the user X, the offset 1=26 bytes (14 bytes of MAC header+12 bytes (the number of bytes up to the source address of the IPv4 header))*8 bits=208 bits is set to the information of the pattern extraction position, and the length 1=4*8 bits (length of IP source address field)=32 bits is set, as shown in the packet example 1 of the table A.

Also, as the information of the pattern extraction position for counting up the statistic information by specifying an application by the TCP destination port No., the packet example 2 is set with the offset 2=36 bytes (14 bytes of MAC header+20 bytes of IP header+2 bytes (the number of bytes up to the TCP destination port No.))*8 bits=288 bits and the length 2=2*8 bits (length of TCP destination port No. field)=16 bits.

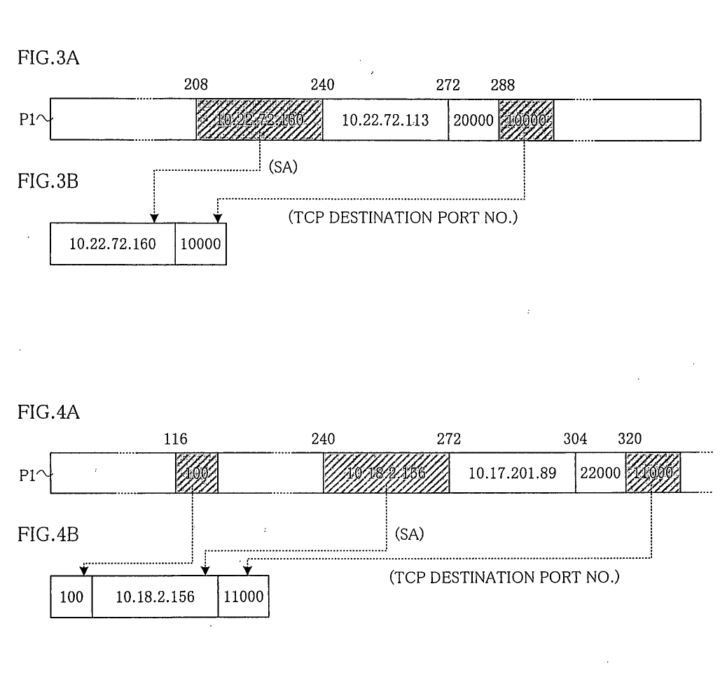

Accordingly, in the case of the reception packet example 1 shown in FIG. 3A, two patterns of the pattern extraction position (208, 32) and (288, 16) are interconnected according to the order of the pattern extraction position as shown by hatching in FIG. 3A, and a signal S2 as the retrieval pattern shown in FIG. 3B is transmitted to the pattern retrieving portion 3.

In the pattern retrieving portion 3 having received such a retrieval pattern, a retrieval is performed from the table B shown in FIG. 5 based on the retrieval pattern. Since an address “1100” is hit in the packet example 1, this hit address “1100” is returned to the pattern extracting portion 2 in the form of the signal S3.

The packet extracting portion 2 having received this signal S3 makes the hit address “1100” offset for the statistic information base address=“80000000” set for the packet example 1 in the table A, transmits an access address “80000100” in the form of a signal S4 to the statistic information memory 4, and counts up the statistic information memory 4 to “1” in the example of FIG. 5.

[Reception Packet Example (Pattern Example) 2]

Hereinafter, it is supposed that the packet P1 of a user Y (not shown) having received from the external network is the Ether (registered trademark) frame, has a tag (single stage), and is set for the IPv4 (Ethernet II form), the TCP, the application using the TCP destination port No. “11000”, and the error packet of TTL=“0” (packet example 2).

When receiving the packet P1, the pattern extracting portion 2 refers to the packet type field and the error type field in the table A. Since the packet type is {tag presence=“1”, type value=“0800 (IPv4)”, protocol value=“6” (TCP)} and the error type is TTL=“0” (error presence) in this example, the packet extracting portion 2 retrieves such a pattern and generates the retrieval pattern for the pattern retrieving portion 3 by using the information of the pattern extraction position of the entry.

Supposing that as the information for identifying the user Y, VID of a tag in the IPv4 frame tagged is used as shown in FIG. 10B or 10D, the information of the pattern extraction position is set to have the offset 1=14*8+4 bits=116 bits (12 bytes of MAC destination address/source address+2 bytes of tag identifier+4 bits (the number of bits up to VID of tag TCI)) and the length 1=12 bits (length of VID field).

Also, it is supposed that as the information of the pattern extraction position for counting the statistic information by specifying the application by the TCP destination port No., the offset 3=40 bytes (18 bytes of MAC header tagged (single stage)+20 bytes of IP header+2 bytes (the number of bytes up to the TCP header destination port No.)*8 bits=320 bits, and the length 3=2*8 bits (length of TCP destination port No.)=16 bits are set. Furthermore, when it is desired that an error count is extracted or collected per IP source address in order to specify the user Y transmitting the error packet, the offset 2=30 bytes (18 bytes of MAC header tagged (single stage)+12 bytes (the number of bytes up to source address of IP header))*8 bits=240 bits, and the length 2=4*8 bits (the length of IP source address field)=32 bits are set.

Accordingly, the pattern extracting portion 2 extracts the patterns of the pattern extraction positions (116, 12), (240, 32), and (320, 16) as shown by hatching in FIG. 4A to be sequentially interconnected, so that the pattern is provided to the pattern retrieving portion 3 in the form of the signal S2 of the retrieval pattern as shown in FIG. 4B.

As a result of retrieving the retrieval pattern shown in FIG. 4B, the address “0100” is hit in the table B in the pattern retrieving portion 3. Therefore, the hit address “0100” that is the retrieval result is returned to the pattern extracting portion 2 in the form of the signal S3. The pattern extraction portion 2 provides an access address “8000100” that is the statistic information base address in the table A to which the hit address “0100” is added, to the statistic information memory 4 in the form of the signal S4 and counts up the statistic information to “10” in this example.

Thus, while the pattern retrieving portion 3 performs a retrieval with the retrieval pattern by the signal S2 transmitted from the pattern extracting portion 2, it is extremely wasteful to preregister all of the retrieval patterns in the tables A and B in a network or the like where more than several thousands of user terminals exist, so that numerous retrieval patterns are not registered, which leads to failures in their retrievals.

Therefore, when receiving a notification of a retrieval failure in the form of the signal S3 from the pattern retrieving portion 3, the pattern extracting portion 2 confirms in the table A whether or not the learning flag is set in the received packet in order to generate the retrieval pattern.

As a result, since the learning flag is set to “0” in the reception packet example 1, no more processing is performed. However, since the learning flag is set to “1” in the reception packet example 2, the pattern extracting portion 2 instructs the pattern retrieving portion 3 to newly register a mishit retrieval pattern in the table B by transmitting a signal S5 shown by dotted lines, in a case that a mishit occurs in the table B in the packet example 2. Then, the memory address to the statistic information memory 4 is generated by using the registered address as an offset for the statistic information base address, and the statistic information is counted up.

### Embodiment 2

In the case of the above-mentioned embodiment 1, the packet type, the error type, and the pattern extraction position of the reception packet are all checked in the table A of the pattern extracting portion 2, and the generation of the retrieval patterns shown in FIGS. 3A, 3B, 4A and 4B is required. In this case, the data processing amount by software of the pattern extracting portion 2 becomes extremely large.

Therefore, in the embodiment 2, the table A of the pattern extracting portion 2 and the table B of the pattern retrieving portion 3 are respectively separated so that the tables are retrieved in a partially and mutually associated manner, thereby enabling a processing load of the pattern extracting portion 2 to be reduced and the speed of the operation to be more enhanced.

Therefore, as shown in FIGS. 6A and 6B, the table A of the pattern extracting portion 2 is firstly separated into a table A-1 shown in FIG. 6A and a table A-2 shown in FIG. 6B.

Namely, the table A-1 is composed of a table concerning the packet type field and the error type field in the table A shown in FIG. 2, and the table A-2 is composed by the combination of the statistic information base address, the learning flag, and the pattern extraction position in the table A.

In the table A-1, as a packet (pattern) α, the pattern extraction positions {(96, 16), (176, 8), (184, 8)} are set, which specify the offsets 1-3 and the lengths 1-3 so as to extract the fields of the “frame type”, the “TTL”, and the “protocol” in the tagless IPv4 frame shown in FIGS. 10A and 10C. Also, in the case of a packet (pattern), the pattern extraction positions {(96, 16), (128, 16), (208, 8), (216, 8)} are set. In the case of the IPv4 frame in which the tag identifier is set as shown in FIGS. 10B and 10D, the offset and length for the bit of the tag identifier are added.

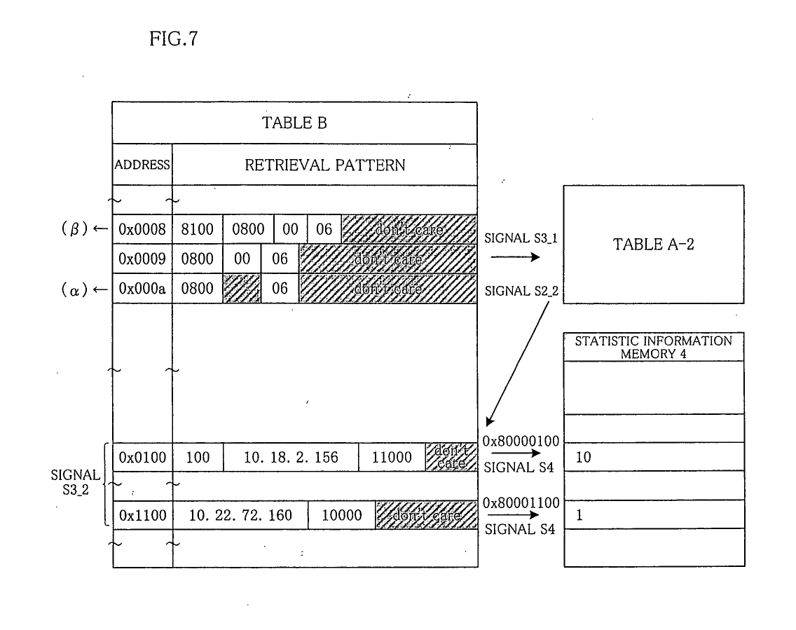

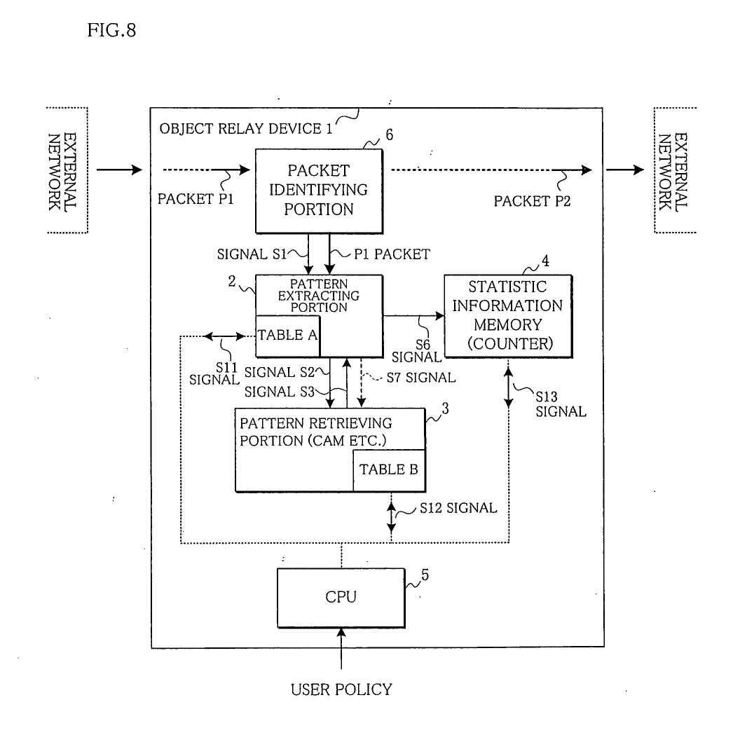

The table A-1 is connected to the table A-2 not directly but through the table B of FIG. 7. Namely, a packet a of the table A-1 hits in an address “000a” in the table B of FIG. 7. This is because the value of the “frame type” field is “0800”, the value of the “TTL” field is “error absence”, and the value of the “protocol” field is “06” indicating the TCP.

Also, in the case of the packet β, the packet hits in the address “0008” of FIG. 7. This indicates that the value of the tag “8100” is set in the offset 1=“96” and the length 1=“16”, and otherwise “0800”, “00”, and “06” hit in the form of the packet a being shifted by tag field. It is to be noted that “TTL”=“00” indicates the error presence.

Thus, as a result of retrieving the retrieval pattern in FIG. 7, this retrieval result is transmitted to the pattern extracting portion 2 from the pattern retrieval portion 3 in the form of a signal S3_1 composing the signal S3. Therefore, in the case of the packet a, the pattern extraction positions {(208, 32), (288, 16)} are retrieved in the same way as the packet example 1 of the table A shown in FIG. 2 corresponding to the hit address “000a” in the case of the packet a. As a result the pattern extracting portion 2 checks the retrieval pattern in other areas of the table B in FIG. 7 in the same way as the example of FIGS. 3A and 3B in the form of a signal S2_2 composing the signal S2 for the pattern retrieving portion 3.

As a result, since an address “1100” hits in the table B of FIG. 7, a signal 4 is provided to the statistic information memory counter 4 in the form of the signal S4 in the same way as the above-mentioned embodiment 1.

Also, since the hit address “0008” is transmitted to the pattern extraction portion 2 in the table B of FIG. 7 in the case of the packet β, the pattern extraction positions {(116, 12), (240, 32), (320, 16)} are transmitted to the pattern retrieving portion 3 in the form of the signal S2_2 based on the hit address “0008” by referring to the table A-2 in the pattern extracting portion 2. Accordingly, by referring to table B, the address “0100” hits in the pattern retrieving portion 3, and the statistic information memory 4 is counted up by the signal 4 in the same way as the cases of FIGS. 4A, 4B, and FIG. 5.

### Embodiment 3

Statistic information is always extracted by software processing (firmware processing) with the tables in the above-mentioned embodiments 1 and 2, which have disadvantages that for retrieving the pattern extraction position by referring to each of the tables for the received packet, the data processing amount remains large even the table is separated as in the embodiment 2.

Accordingly, in this embodiment 3, the packet identifying portion 6 composed of hard logics in the same way as the prior art is used in the relay device 1, and the identification result of the packet identifying portion 6 is transmitted to the pattern extraction portion 2 in the form of the signal S1.

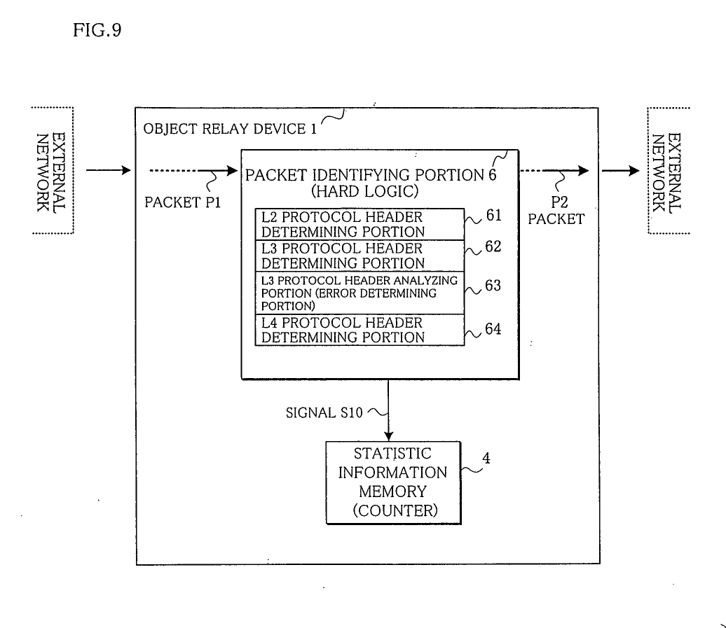

Namely, the packet identifying portion 6 is provided with the L2 protocol header portion 61, the L3 protocol header determining portion 62, the L3 protocol header analyzing portion 63, and the L4 protocol header determining portion 64 in the same way as the prior art example shown in FIG. 9, thereby preliminarily realizing by hardware, analyses of a packet header and user data, a determination of a protocol type, specifications of a user application, a user, an arbitrary flow per user, a determination of an error packet and the like which are all essential for statistic information and which are considered to be important, and executing other processing by using the table by software.

Accordingly, the packet identifying portion 6 transmits as the packet P1 information of the packet type and the error type, as well as packet information of an entire packet or of a length statically set, which is enough for the pattern extracting portion 2 to extract a pattern.

In the case of the above-mentioned reception packet example 1, the packet identifying portion 6 detects that the packet is not tagged, is the IPv4+TCP packet, and is errorless to notify the packet to the pattern extracting portion 2 in the form of the signal S1.

The pattern extracting portion 2 extracts the information of the pattern extraction position by using the signal S1 and a packet P1, and the above-mentioned table A or tables A-1, A-2.

Also, in the case of the above-mentioned reception packet example 2, the packet identifying portion 6 notifies that the packet has a tag (single stage), the IPv4+TCP packet, and the error packet of TTL=“0” to the pattern retrieving portion 3. The pattern retrieving portion 3 performs the same operation as the above based on the signal S1.

It is to be noted that in the above-mentioned embodiments, the frames of FIGS. 10A-10D are taken as examples. However, the present invention is not limited to these frames, and the frame itself is not limited to the IPv4. It is needless to say that the present invention can be similarly applied to the case of the IPv6.

As described above, by the statistic information extraction method and device according to the present invention, the extraction of the statistic information to which the user policy is reflected can be realized, an assignment of a statistic information memory address can be realized when a statistic information extraction trigger occurs, and the extraction of statistic information whose extraction and registration are statistically difficult can be realized.

What is claimed is:

1. A statistic information extraction method comprising:
a first step of setting a table for retrieving a pattern to which a user policy is reflected;
a second step of retrieving the pattern from received packets based on the table; and
a third step of storing statistic information of the pattern retrieved.

2. The statistic information extraction method as claimed in claim 1, wherein the first step sets in the table whether or not the received packet should be made a learning object, and the second step adds to the table a pattern unable to be retrieved if the received packet is set as the learning object in the table when the pattern is unable to be retrieved.

3. The statistic information extraction method as claimed in claim 1, wherein the first step sets in a first table a packet type, an error type, and a pattern extraction position within a received packet corresponding to those types, and further sets in a second table a retrieval pattern corresponding to the pattern extraction position.

4. The statistic information extraction method as claimed in claim 3, wherein the first step sets the first and the second table separately, and retrieves both tables in a partially and mutually associated manner.

5. The statistic information extraction method as claimed in claim 3, wherein only when types of the received packet correspond to both types set in the first table, the second step retrieves, from the second table, a retrieval pattern at the pattern extraction position corresponding to the both types.

6. The statistic information extraction method as claimed in claim 5, wherein the first step sets the packet type and the error type in a hard logic, and the second step retrieves the pattern extraction position from the first table based on the packet type and the error type identified by the hard logic, and further retrieves, from the second table, the retrieval pattern corresponding to the pattern extraction position.

7. The statistic information extraction method as claimed in claim 1, wherein the third step counts the retrieved pattern, and makes the count the statistic information.

8. A statistic information extraction device comprising:
a first means setting a table for retrieving a pattern to which a user policy is reflected;
a second means retrieving the pattern from received packets based on the table; and
a third means storing statistic information of the pattern retrieved.

9. The statistic information extraction device as claimed in claim 8, wherein the first means sets in the table whether or not the received packet should be made a learning object, and the second means adds to the table a pattern unable to be retrieved if the received packet is set as the learning object in the table when the pattern is unable to be retrieved.

10. The statistic information extraction device as claimed in claim 8, wherein the first means sets in a first table a packet type, an error type, and a pattern extraction position within a received packet corresponding to those types, and further sets in a second table a retrieval pattern corresponding to the pattern extraction position.

11. The statistic information extraction device as claimed in claim 10, wherein the first means sets the first and the second table separately, and retrieves both tables in a partially and mutually associated manner.

12. The statistic information extraction device as claimed in claim 10, wherein only when types of the received packet correspond to both types set in the first table, the second means retrieves, from the second table, a retrieval pattern at the pattern extraction position corresponding to the both types.

13. The statistic information extraction device as claimed in claim 12, wherein the first means further comprises a hard logic identifying the packet type and the error type, and the second means retrieves the pattern extraction position from the first table based on the packet type and the error type identified by the hard logic, and further retrieves, from the second table, the retrieval pattern corresponding to the pattern extraction position.

14. The statistic information extraction device as claimed in claim 8, wherein the third means counts the retrieved pattern, and makes the count the statistic information.
